(19) United States
(12) Patent Application Publication
(10) Pub. No.: US 2008/0238530 A1
(43) Pub. Date: Oct. 2, 2008

(54) Semiconductor Device Generating Voltage for Temperature Compensation

(75) Inventors: Takashi Ito, Tokyo (JP); Naruaki Kiriki, Tokyo (JP); Tadaaki Yamauchi, Tokyo (JP); Minekazu Ono, Tokyo (JP); Tsutomu Nagasawa, Tokyo (JP); Hidehiko Kuge, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/076,991

(22) Filed: Mar. 26, 2008

(30) Foreign Application Priority Data
Mar. 28, 2007 (JP) 2007-084558
Mar. 29, 2007 (JP) 2007-088320
Feb. 8, 2008 (JP) 2008-029309

(51) Int. Cl. H01L 37/00

(52) U.S. Cl. 327/513

(57) ABSTRACT

An input transistor unit includes a first transistor having a control electrode to which a reference voltage is supplied. An output transistor unit includes a diode-connected second transistor. At least one of the input transistor unit and the output transistor unit further includes a third transistor that is diode-connected and connected in series with the corresponding first transistor or the second transistor and outputs a current in the same direction as the corresponding transistor does. The number of transistors included in the input transistor unit and the number of transistors included in output transistor unit are different from each other. The size of transistors included in the input transistor unit differs from that of transistors included in the output transistor unit.

### BACKGROUND OF THE INVENTION

1. Field of the Invention

The present invention relates to a semiconductor device, and particularly to a semiconductor device generating a voltage for temperature compensation.

2. Description of the Background Art

There have been developed flash memories having a circuit that generates, based on an external voltage, a voltage different from the external voltage, as write voltage, read voltage and erase voltage for memory cells.

In general, characteristics of memory cells vary with temperature. Therefore, in such flash memories, write voltage, read voltage and erase voltage for memory cells need to be varied in accordance with the temperature characteristics of memory cells. That is, temperature compensation needs to be performed. As a circuit for performing such temperature compensation, for example, there is a circuit for generating an output voltage, in which a reference input voltage is caused to have a temperature characteristic. In such a temperature compensation voltage generation circuit, for example, a current mirror circuit is used.

Regarding a voltage generation circuit using a current mirror circuit, for example, the following configuration is disclosed in Japanese Patent Laying-Open No. 2001-298332 (Patent Document 1). That is, a first transistor and a second transistor constitute a current mirror circuit. A third transistor, to which a comparison voltage, which is a predetermined constant voltage, is input through an inverted input terminal, is connected in series to the first transistor. A fourth transistor, to which a feedback voltage, which is in proportion to an output voltage of the third transistor, is input through a non-inverted input terminal, is connected in series to the second transistor. A current source supplies a predetermined current to the first transistor, the second transistor, the third transistor and the fourth transistor. An offset circuit is connected in series to the third transistor, and provides a predetermined input offset voltage between the inverted input terminal and the non-inverted input terminal.

Also disclosed in Japanese Patent Laying-Open No. 2001-068976 (Patent Document 2) is the following configuration. That is, an oscillator includes a ring oscillator section made of a CMOS inverter and a voltage supply section supplying a voltage to the ring oscillator section in a semiconductor integrated circuit device. First compensation means is included in the voltage supply section that cancels the temperature characteristic of an oscillated frequency of the ring oscillator section. Second compensation means cancels dispersion in oscillated frequency caused by dispersion from the design value of the threshold voltage of MOS transistors having conductive types different from each other, which constitute the CMOS inverter.

Also disclosed in Japanese Patent Laying-Open No. 2000-163970 (Patent Document 3) is the following configuration. That is, a back-bias circuit applies to a semiconductor device composed of a plurality of transistors a back-bias voltage for correcting the threshold voltage of the transistors. A back-bias generation circuit is made of a charge pump circuit, and outputs a back-bias voltage. A detection circuit detects a back-bias voltage from the back-bias generation circuit, and controls on/off operations of the back-bias generation circuit based on the voltage.

Also disclosed in Japanese Patent Laying-Open No. 2000-075946 (Patent Document 4) is the following configuration. That is, the output voltage of a diode has a negative temperature coefficient. The gate of a metal-oxide semiconductor (MOS) transistor for temperature compensation is connected to one end of the diode. Current supply means supplies to the MOS transistor for temperature compensation a drain current set such that the MOS transistor for temperature compensation operates in an area where the gate-source voltage has a positive temperature coefficient for compensating the negative temperature coefficient of the diode. A voltage obtained by adding the output voltage of the diode to the gate-source voltage of the MOS transistor for temperature compensation is output as a reference voltage.

Also disclosed in Japanese Patent Laying-Open No. 10-239357 (Patent Document 5) is a circuit that generates a negative voltage in the inside of a chip by a charge pump. That is, a negative voltage detection circuit detects whether or not the output voltage of the charge pump is a negative voltage, and outputs a control signal. The negative voltage detection circuit detects the negative voltage by comparing the voltage being −(1/n) times (n is a natural number) the output voltage of the charge pump with a positive reference voltage. When the output voltage of the charge pump becomes lower than a desired voltage, operations of the charge pump are stopped. Otherwise, control signals to operate the charge pump are generated. By such feed back control, the output voltage of the charge pump is controlled so as to become a desired negative voltage.

Also disclosed in Japanese Patent Laying-Open No. 2004-164746 (Patent Document 6) is a configuration for supplying a high voltage being not affected by temperature variations to a control gate, a source and the like at the time when data is written and erased into a nonvolatile semiconductor memory. That is, the feedback voltage obtained by resistor-dividing an output high voltage is compared with a reference voltage generated in a reference voltage generation circuit. The configuration is made such that a step-up circuit for stepping up an external power source voltage is on/off controlled with this comparison result to control the value of the output high voltage. The circuit constant of the reference voltage generation circuit is determined so that the temperature coefficient of the output high voltage is equal to the temperature coefficient of the threshold voltage of a MOS switching transistor that turns on/off of applying a high voltage to a memory transistor by giving a temperature coefficient to the reference voltage.

Also disclosed in Japanese Patent Laying-Open No. 09-083309 (Patent Document 7) is a configuration of generating a voltage for temperature compensation for stabilizing the oscillation frequency against temperature variations.

Also disclosed in Japanese Patent Laying-Open No. 2000-252804 (Patent Document 8) is a configuration of generating, in the over-current detection of an output transistor, a reference voltage for over-current detection for compensating the temperature characteristic of the output transistor.

In the conventional temperature compensation voltage generation circuits as described above, there are some cases where the output voltage value largely deviates from the input voltage value. For example, if an output voltage becomes substantially small with respect to a reference input voltage, it is considered to set the reference input voltage large in advance. With such a method, however, a circuit for increasing or decreasing the reference input voltage is additionally needed. This causes the circuit scale to become large.

The configuration described in Patent Document 1 is for a differential amplifier circuit, and therefore stepping up or stepping down the input voltage is impossible. It is also impossible to cause the input voltage to have a temperature characteristic. In the configuration described in Patent Document 2, stepping up or stepping down the input voltage is impossible. In the configurations of Patent Document 3 and Patent Document 4, stepping up or stepping down the input voltage is impossible, and it is also impossible to cause the input voltage to have a temperature characteristic.

Further, in the configuration of Patent Document 5, the detected level of the negative voltage can be varied by varying the reference voltage. However, in the configuration of Patent Document 5, it is intended that a reference voltage having less temperature dependence and supply voltage dependence be generated using a bandgap reference circuit and the like so as to prevent the detected level of the negative voltage from being dependent on the supply voltage and the like. Accordingly, the configuration of Patent Document 5 has a problem that the configuration cannot appropriately cope with the temperature characteristic of an element to which the negative voltage is supplied.

In the configuration of Patent Document 6, a voltage obtained by dividing an output voltage is compared with the reference voltage having the temperature characteristic, and the step-up circuit is controlled based on the result of the comparison, thereby generating the output voltage. In the configuration of Patent Document 6, if a configuration of changing the output voltage by changing the dividing ratio of the output voltage is applied, it is possible to prevent non-uniformity of output voltage values caused by non-uniformity of internal components. However, with such a configuration, the temperature characteristic of the output voltage varies in accordance with the dividing ratio.

The objects of the configurations of Patent Documents 7 and 8 do not lie in coping with the temperature characteristic of an element to which an output voltage is supplied.

### SUMMARY OF THE INVENTION

The present invention has been achieved to solve the above problems, and an object thereof is to provide a semiconductor device that allows an internal voltage to be stabilized regardless of an operating environment.

Another object of the present invention is to provide a semiconductor device that causes an input voltage to have a temperature characteristic and steps up or steps down the input voltage, and that enables simplification of a circuit configuration.

Still another object of the present invention is to provide a semiconductor device that can appropriately cope with characteristics derived from external factors of an element to which an output voltage is supplied and prevent non-uniformity among output voltage values and characteristics of the output voltages.

A semiconductor device according to an embodiment of the present invention is, in summary, that a first input transistor unit includes a first transistor having a control electrode to which a reference voltage is supplied. A first output transistor unit includes a diode-connected second transistor. The first output current control circuit causes a current corresponding to a current flowing between conductive electrodes of the first transistor to flow between conductive electrodes of the second transistor. At least one of the first input transistor unit and the first output transistor unit further includes one or more third transistors being diode-connected and connected in series with corresponding one of the first transistor and the second transistor to output a current in the same direction as the direction of an output current of the corresponding one of the first transistor and the second transistor. The total number of the first transistors and the third transistors in the first input transistor unit differs from the total number of the second transistors and the third transistors in the first output transistor unit. The size of the first transistor and the size of the one or more third transistors in the first input transistor unit differ from the size of the second transistor and the size of the one or more third transistors in the first output transistor unit. In the semiconductor device, a voltage at the control electrode of the second transistor is the output voltage.

A semiconductor device according to another embodiment of the present invention is, in summary, that a first reference voltage generation circuit generates a first reference voltage having a voltage value varying in accordance with an external factor. An output voltage generation circuit performs a comparison of the first reference voltage with a comparison object voltage and generates an output voltage based on the result of the comparison. A second reference voltage generation circuit generates, based on the first reference voltage, a plurality of voltages smaller than the first reference voltage and selects one of the plurality of voltages and outputs the selected voltage as a second reference voltage. A comparison object voltage generation circuit generates the comparison object voltage based on the output voltage and the second reference voltage.

According to the embodiment of the present invention, the size of the first transistor and the size of the one or more third transistors in the first input transistor unit differ from the size of the second transistor and the size of the one or more third transistors in the first output transistor unit. This allows a voltage to be generated by causing a reference input voltage to have a temperature characteristic. The total number of the first transistor and the third transistors in the first input transistor unit differs from the total number of the second transistor and the third transistors in the first output transistor unit. This allows a voltage to be generated by stepping up or stepping down the reference voltage. A circuit for stepping up or stepping down the reference voltage needs not to be additionally provided. This can cause simplification of the circuit configuration.

Therefore, it is possible to cause an input voltage to have a temperature characteristic and to step up the input voltage, and the circuit configuration can be simplified.

According to another embodiment of the present invention, a first reference voltage generation circuit generates a first reference voltage having a voltage value varying in accordance with an external factor. An output voltage generation circuit performs a comparison of the first reference voltage received from the first reference voltage generation circuit with a comparison object voltage received from the comparison object voltage generation circuit and generates an output voltage based on the result of the comparison. This makes it possible to appropriately cope with characteristics derived from external factors of an element to which an output voltage is supplied.

Further, a second reference voltage generation circuit generates, based on the first reference voltage, a plurality of voltages smaller than the first reference voltage and selects one of the plurality of voltages and outputs the selected voltage as a second reference voltage. Then, a comparison object voltage generation circuit generates the comparison object voltage based on the output voltage received from the output voltage generation circuit and the second reference voltage received from the second reference voltage generation circuit. This enables non-uniformity of internal components and the like to be coped with, achieving fine adjustment of the output voltage. This also enables the value of the output voltage to be coped with, achieving fine adjustment of characteristics of the output voltage.

Therefore, it is possible to appropriately cope with characteristics derived from external factors of an element to which the output voltage is supplied and to prevent non-uniformity among voltage values and characteristics of the output voltages.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a functional block diagram showing the configuration of a semiconductor device 301 according to a first embodiment of the present invention.

FIG. 2 is a circuit diagram showing the configuration of a temperature compensation voltage generation circuit 51 according to the first embodiment of the present invention.

FIG. 3 is a circuit diagram showing the configuration in which the circuit configuration of temperature compensation voltage generation circuit 51 is partially omitted.

FIG. 4 is a graph showing one example of the temperature characteristic of a temperature compensation voltage VT.

FIG. 5 is a circuit diagram showing the configuration of a temperature compensation voltage generation circuit 52 according to a second embodiment of the present invention.

FIG. 6 is a circuit diagram showing the configuration of a temperature compensation voltage generation circuit 53 according to a third embodiment of the present invention.

FIG. 7 is a graph showing one example of the temperature characteristic of temperature compensation voltage VT.

FIG. 8 is a circuit diagram showing the configuration of a temperature compensation voltage generation circuit 54 according to a fourth embodiment of the present invention.

FIG. 9 is a functional block diagram showing the configuration of a semiconductor device 401 according to a fifth embodiment of the present invention.

FIG. 10 is a circuit diagram showing the configuration of a first reference voltage generation circuit 101 in semiconductor device 401 according to the fifth embodiment of the present invention.

FIG. 11 is a circuit diagram showing the configuration of a second reference voltage generation circuit 102 in semiconductor device 401 according to the fifth embodiment of the present invention.

FIG. 12 is a circuit diagram showing the configuration of a comparison object voltage generation circuit 103 and an output voltage generation circuit 104 in semiconductor device 401 according to the fifth embodiment of the present invention.

FIG. 13 is a graph showing a relationship between the voltage value and the temperature characteristic of an output voltage VOUT of semiconductor device 401 according to the fifth embodiment of the present invention.

FIG. 14 is a functional block diagram showing the configuration of a semiconductor device 402 according to a sixth embodiment of the present invention.

### DESCRIPTION OF THE PREFERRED EMBODIMENTS

Embodiments of the present invention will be described below with reference to the drawings. It is to be noted that parts identical or equivalent in the drawings are indicated by the same reference numerals, and description thereof is not repeated.

### First Embodiment

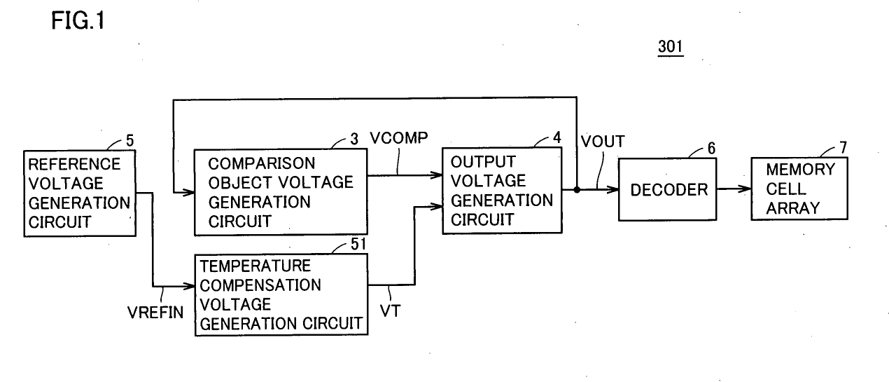

FIG. 1 is a functional block diagram showing the configuration of semiconductor device 301 according to a first embodiment of the present invention.

With reference to FIG. 1, semiconductor device 301 includes temperature compensation voltage generation circuit 51, a comparison object voltage generation circuit 3, an output voltage generation circuit 4, a reference voltage generation circuit 5, a decoder 6 and a memory cell array 7.

Based on a reference input voltage VREFIN received from reference voltage generation circuit 5, temperature compensation voltage generation circuit 51 generates temperature compensation voltage VT whose value varies in accordance with ambient temperature, which is an external factor.

Output voltage generation circuit 4 compares temperature compensation voltage VT received from temperature compensation voltage generation circuit 51 with a comparison object voltage VCOMP received from comparison object voltage generation circuit 3, generates output voltage VOUT based on the comparison result, and outputs it to decoder 6 and comparison object voltage generation circuit 3. Note that output voltage generation circuit 4 may be a voltage down converter (VDC), be a regulator, and have the configuration including a charge pump as described later.

Based on output voltage VOUT received from output voltage generation circuit 4, comparison object voltage generation circuit 3 generates comparison object voltage VCOMP having a voltage value smaller than that of output voltage VOUT. With such a configuration, the withstand voltage of transistors and the like included in output voltage generation circuit 4 can be reduced. For example, the voltage that a comparison circuit of output voltage generation circuit 4 receives can be made smaller than output voltage VOUT, and therefore the transistors included in the comparison circuit can be prevented from being broken.

Comparison object voltage generation circuit 3 can change the value of comparison object voltage VCOMP, e.g., by an internal switch. With such a configuration, the value of output voltage VOUT can be changed.

Based on output voltage VOUT received from output voltage generation circuit 4, decoder 6 generates write voltage, read voltage, erase voltage and the like, and outputs them to a memory cell array 7. For example, based on output voltage VOUT received from output voltage generation circuit 4, decoder 6 supplies voltage to word lines in memory cell array 7.

For example, memory cell array 7 includes a plurality of memory cells that store data, and stores data, outputs the stored data, and erases the stored data based on write voltage, read voltage, erase voltage and the like received from decoder 6.

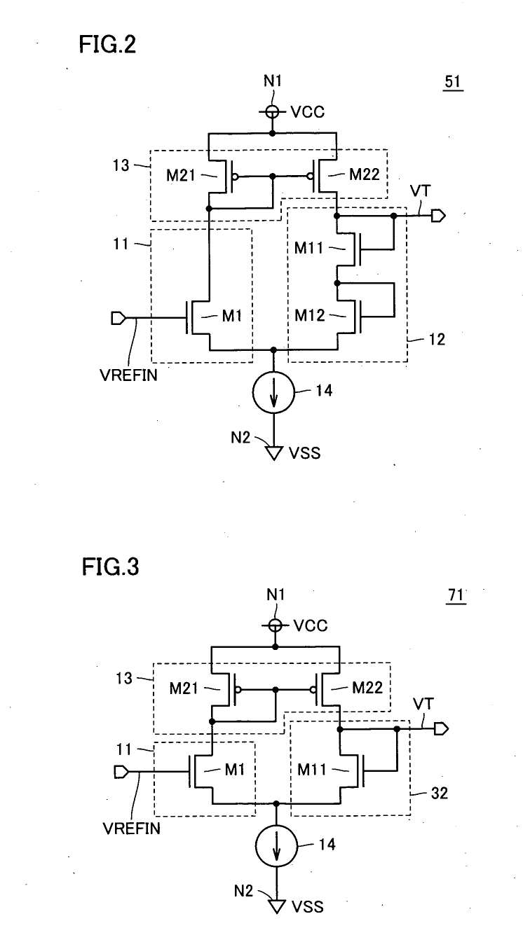

FIG. 2 is a circuit diagram showing the configuration of a temperature compensation voltage generation circuit 51 according to the first embodiment of the present invention.

With reference to FIG. 2, temperature compensation voltage generation circuit 51 is provided with an input transistor unit 11, an output transistor unit 12, a current mirror circuit (output current control circuit) 13 and a constant current source 14. Input transistor unit 11 includes an N-channel MOS transistor (insulated-gate field-effect transistor) M1. Output transistor unit 12 includes N-channel MOS transistors M11 and M12. Current mirror circuit 13 includes P-channel MOS transistors M21 and M22.

N-channel MOS transistor M1 has its gate to which reference input voltage VREFIN is supplied, its source connected to a first terminal of constant current source 14, and its drain connected to the drain of P-channel MOS transistor M21. A second terminal of constant current source 14 is connected to a ground potential node N2 to which a ground voltage VSS is supplied.

N-channel MOS transistors M11 and M12 are each diode-connected. N-channel MOS transistor M12 outputs a current in the same direction as that of an output current of N-channel MOS transistor M11. More specifically, N-channel MOS transistor M11 has its gate and drain connected to each other and its source connected to the gate and the drain of N-channel MOS transistor M12. N-channel MOS transistor M12 has its gate and drain connected to each other and its source connected to the first terminal of constant current source 14.

P-channel MOS transistor M21 has its gate and drain connected to each other and its source connected to a power source potential node N1 to which a supply voltage VCC is supplied.

P-channel MOS transistor M22 has its gate connected to the gate and the drain of P-channel MOS transistor M21, its drain connected to the gate and the drain of N-channel MOS transistor M11, and its source connected to power source potential node N1.

P-channel MOS transistors M21 and M22 in current mirror circuit 13 have approximately the same characteristics. With such a configuration, the output current, that is, the current from the drain to the source of N-channel MOS transistor M1 can be approximately equal to the output current, that is, the current from the drain to the source through P-channel MOS transistor M22 and N-channel MOS transistors M11 and M12. The gate-source voltage of each of N-channel MOS transistors M1 and M12 becomes equal to that of N-channel MOS transistor M1. Note that the mirror ratio of current mirror circuit 13 may be other than 1 to 1.

Temperature compensation voltage generation circuit 51 outputs the voltage at the drain and gate of N-channel MOS transistor M11 as temperature compensation voltage VT. N-channel MOS transistor M11 is diode-connected, and therefore temperature compensation voltage VT is a gate voltage of N-channel MOS transistor M11 at the stable operation point.

The size, that is, L/W of N-channel MOS transistor M1 differs from the size of N-channel MOS transistors M1 and M12. L represents the channel length and W represents the channel width. Therefore, temperature compensation voltage VT varies in accordance with temperature. By changing the magnitude correlation between the size of N-channel MOS transistor M1 and the size of N-channel MOS transistors M11 and M12, it is possible to adjust the temperature characteristic, that is, the degree at which temperature compensation voltage VT varies as temperature varies.

N-channel MOS transistors M11 and M12 have approximately the same size. Accordingly, by changing the number of transistors included in output transistor unit 12, the voltage offset value of temperature compensation voltage VT can be increased by a factor of the number of transistors included in output transistor unit 12, that is, by a factor of an integer.

FIG. 3 is a circuit diagram showing the configuration in which the circuit configuration of temperature compensation voltage generation circuit 51 is partially omitted.

With reference to FIG. 3, temperature compensation voltage generation circuit 71 is provided with an output transistor unit 32 instead of output transistor unit 12. Output transistor unit 32 includes N-channel MOS transistor M11. That is, temperature compensation voltage generation circuit 71 has a configuration without N-channel MOS transistor M12 as compared with temperature compensation voltage generation circuit 51.

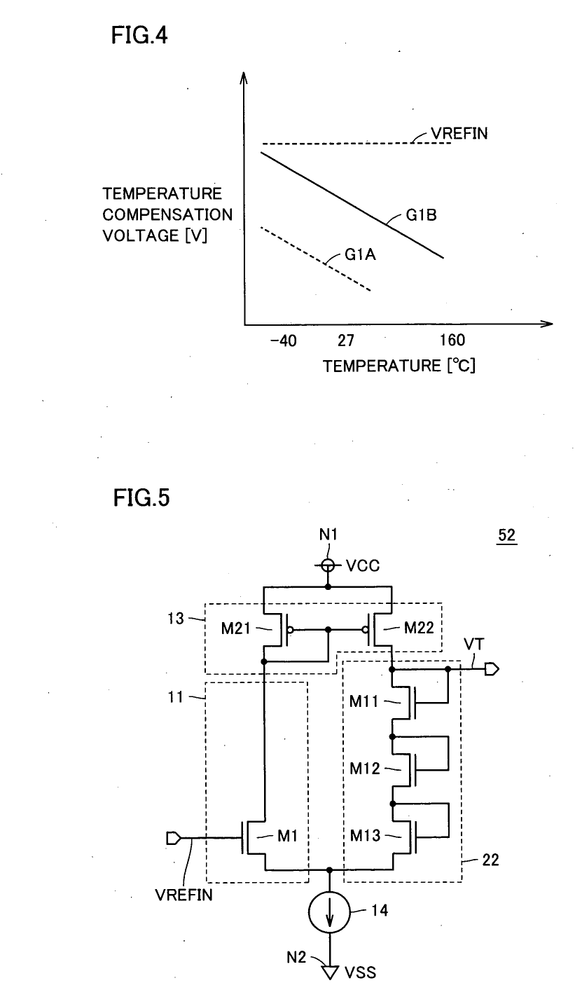

FIG. 4 is a graph showing one example of the temperature characteristic of a temperature compensation voltage VT.

With reference to FIG. 4, in temperature compensation voltage generation circuit 71, for example, if the size, that is, L/W of N-channel MOS transistor M1 is smaller than that of N-channel MOS transistor M11, temperature compensation voltage VT has a negative temperature characteristic as indicated by G1A of the graph.

In this case, temperature compensation voltage VT is considerably smaller than reference input voltage VREFIN. For this reason, for example, a circuit for stepping up reference input voltage VREFIN needs to be prepared separately in addition to temperature compensation voltage generation circuit 71 to generate temperature compensation voltage VT as indicated by G1B of the graph. This makes the circuit scale large.

Referring again to FIG. 2, in temperature compensation voltage generation circuit 51 according to the first embodiment of the present invention, output transistor unit 12 further includes N-channel MOS transistor M12 as compared with temperature compensation voltage generation circuit 71. N-channel MOS transistor M12 is diode-connected and connected in series with N-channel MOS transistor M11, and outputs a current in the same direction as that of the output current of N-channel MOS transistor M11. With such a configuration, the voltage at the drain and gate of N-channel MOS transistor M11 of temperature compensation voltage generation circuit 51 is larger than that in temperature compensation voltage generation circuit 71 by the voltage between the gate and source of N-channel MOS transistor M12. That is, temperature compensation voltage VT is twice the gate-source voltage of N-channel MOS transistor M1. Therefore, in temperature compensation voltage generation circuit 51 according to the first embodiment of the present invention, temperature compensation voltage VT can be prevented from largely deviating from reference input voltage VREFIN without separate provision of a circuit for stepping up reference input voltage VREFIN.

In conventional temperature compensation voltage generation circuits, a circuit of stepping up or stepping down the reference input voltage needs to be provided additionally so as to prevent the output voltage value from largely deviating from the input voltage value. This causes the circuit scale to become large. With the configurations of Patent Documents 1 to 4, it is not possible to step up or step down the input voltage as well as to cause the input voltage to have a temperature characteristic.

However, in temperature compensation voltage generation circuit 51 according to the first embodiment of the present invention, the size of N-channel MOS transistor M1 included in input transistor unit 11 differs from that of N-channel MOS transistors M11 and M12 included in output transistor unit 12. With such a configuration, a voltage which is generated by causing reference input voltage VREFIN to have a temperature characteristic can be obtained. Also, in temperature compensation voltage generation circuit 51 according to the first embodiment of the present invention, the number of transistors included in output transistor unit 12 is larger than that of transistors included in input transistor unit 11. With such a configuration, a voltage can be generated by stepping up reference input voltage VREFIN. Temperature compensation voltage generation circuit 51 according to the first embodiment of the present invention has a configuration obtained only by adding N-channel MOS transistor M12 to temperature compensation voltage generation circuit 71. A circuit for stepping up reference input voltage VREFIN needs not to be provided additionally, enabling the simplification of the circuit configuration. The current flowing through output transistor unit 12 is the same as that of temperature compensation voltage generation circuit 71, and therefore an increase in power consumption can be prevented.

Thus, in temperature compensation voltage generation circuit 51 according to the first embodiment of the present invention, it is possible to cause the input voltage to have a temperature characteristic as well as to step up the input voltage, and the circuit configuration can be simplified.

It is to be noted that while temperature compensation voltage generation circuit 51 according to the first embodiment of the present invention has a configuration including current mirror circuit 13, this is not restrictive. By supplying voltage to the gate of N-channel MOS transistor M11 based on the output current of N-channel MOS transistor M1, a circuit that causes a current corresponding to a current flowing between the drain and source of N-channel MOS transistor M1 to flow between the drain and source of N-channel MOS transistor M11 may be provided as the output current control circuit, instead of the current mirror circuit.

Next, another embodiment of the present invention will be described with reference to the drawings. It is to be noted that parts identical or equivalent in the drawings are indicated by the same reference numerals, and description thereof is not repeated.

### Second Embodiment

The present embodiment relates to a temperature compensation voltage generation circuit in which transistors included in the output transistor unit is increased as compared with the temperature compensation voltage generation circuit according to the first embodiment. Content other than that described below is the same as the temperature compensation voltage generation circuit according to the first embodiment.

FIG. 5 is a circuit diagram showing the configuration of a temperature compensation voltage generation circuit 52 according to a second embodiment of the present invention.

With reference to FIG. 5, temperature compensation voltage generation circuit 52 includes output transistor unit 22 instead of output transistor unit 12 as compared with the temperature compensation voltage generation circuit of the first embodiment of the present invention. Output transistor unit 22 includes N-channel MOS transistors M11 to M13.

N-channel MOS transistors M11 to M13 are each diode-connected. N-channel MOS transistors M12 and M13 each output a current in the same direction as that of the output current of N-channel MOS transistor M11. More specifically, N-channel MOS transistor M11 has its gate and drain connected with each other and its source connected to the gate and the drain of N-channel MOS transistor M12. N-channel MOS transistor M12 has its gate and drain connected with each other and its source connected to the gate and the drain of N-channel MOS transistor M13. N-channel MOS transistor M13 has its gate and drain connected with each other and its source connected to the first terminal of constant current source 14.

P-channel MOS transistors M21 and M22 in current mirror circuit 13 have approximately the same characteristics. With such a configuration, the output current, that is, the current from the drain to the source of N-channel MOS transistor M1 can be approximately equal to the output current, that is, the current from the drain to the source through P-channel MOS transistor M22 and N-channel MOS transistors M11 to M13. The gate-source voltage of each of N-channel MOS transistors M11 to M13 becomes equal to the gate-source voltage of N-channel MOS transistor M1.

The size, that is, L/W of N-channel MOS transistor M1 differs from the size of N-channel MOS transistors M11 to M13. L represents the channel length and W represents the channel width. Therefore, temperature compensation voltage VT varies in accordance with temperature. By changing the magnitude correlation between the size of N-channel MOS transistor M1 and the size of N-channel MOS transistors M11 to M13, it is possible to adjust the temperature characteristic, that is, the degree at which temperature compensation voltage VT varies as temperature varies.

N-channel MOS transistors M11 to M13 have approximately the same size. Accordingly, by changing the number of transistors included in output transistor unit 22, the voltage offset value of temperature compensation voltage VT can be increased by a factor of the number of transistors included in output transistor unit 12, that is, by a factor of an integer.

In temperature compensation voltage generation circuit 52 according to the second embodiment of the present invention, output transistor unit 22 further includes N-channel MOS transistors M12 and M13 as compared with temperature compensation voltage generation circuit 71 shown in FIG. 3. N-channel MOS transistors M12 and M13 are diode-connected and connected in series with N-channel MOS transistor M11, and each output a current in the same direction as that of the output current of N-channel MOS transistor M11. With such a configuration, the voltage at the drain and gate of N-channel MOS transistor M11 of temperature compensation voltage generation circuit 52 is larger than that in temperature compensation voltage generation circuit 71 by the total of gate-source voltage of N-channel MOS transistors M12 and M13. That is, temperature compensation voltage VT is three times the gate-source voltage of N-channel MOS transistor M1. Therefore, in temperature compensation voltage generation circuit 52 according to the second embodiment of the present invention, temperature compensation voltage VT can be prevented from largely deviating from reference input voltage VREFIN without separate provision of a circuit for stepping up reference input voltage VREFIN.

Other configurations and operations are the same as those in the temperature compensation voltage generation circuit according to the first embodiment, and therefore detailed description is not repeated here.

Thus, in temperature compensation voltage generation circuit 52 according to the second embodiment of the present invention, as in the temperature compensation voltage generation circuit according to the first embodiment of the present invention, it is possible to cause the input voltage to have a temperature characteristic as well as to step up the input voltage, and the circuit configuration can be simplified.

Next, another embodiment of the present invention will be described with reference to the drawings. It is to be noted that parts identical or equivalent in the drawings are indicated by the same reference numerals, and description thereof is not repeated.

### Third Embodiment

The present embodiment relates to a temperature compensation voltage generation circuit in which magnitude correlation between the number of transistors included in the input transistor unit and the number of transistors included in the output transistor unit is reversed as compared with the temperature compensation voltage generation circuit according to the first embodiment. Content other than that described below is the same as the temperature compensation voltage generation circuit according to the first embodiment.

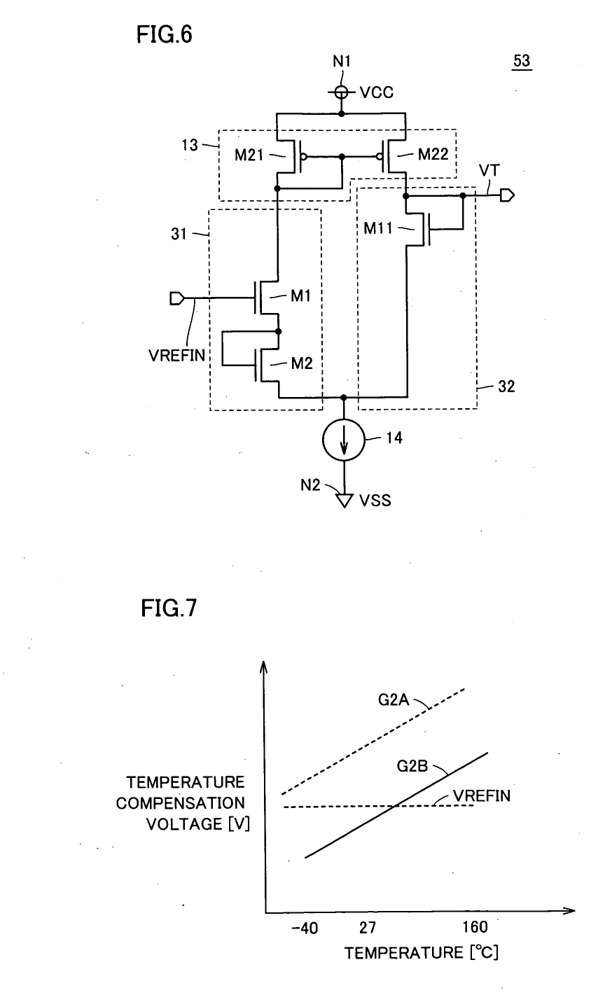

FIG. 6 is a circuit diagram showing the configuration of a temperature compensation voltage generation circuit 53 according to a third embodiment of the present invention.

With reference to FIG. 6, temperature compensation voltage generation circuit 53 includes an input transistor unit 31, instead of input transistor unit 11, and output transistor unit 32, instead of output transistor unit 12, as compared with the temperature compensation voltage generation circuit of the first embodiment of the present invention. Input transistor unit 31 includes N-channel MOS transistors M1 and M2. Output transistor unit 32 includes N-channel MOS transistor M11.

N-channel MOS transistor M1 includes its gate to which reference input voltage VREFIN is supplied, its source connected to the gate and drain of N-channel MOS transistor M2, and its drain connected to the drain of P-channel MOS transistor M21.

N-channel MOS transistor M2 is diode-connected. N-channel MOS transistor M2 outputs a current in the same direction as that of the output current of N-channel MOS transistor M1. More specifically, N-channel MOS transistor M2 has its gate and drain connected with each other and its source connected to the first terminal of constant current source 14. The second terminal of constant current source 14 is connected to ground potential node N2 to which ground voltage VSS is supplied.

N-channel MOS transistor M11 is diode-connected. More specifically, N-channel MOS transistor M11 has its gate and drain connected with each other and its source connected to the first terminal of constant current source 14.

P-channel MOS transistors M21 and M22 in current mirror circuit 13 have approximately the same characteristics. With such a configuration, the output current, that is, the current from the drain to the source of N-channel MOS transistor M1 can be approximately equal to the output current, that is, the current from the drain to the source of P-channel MOS transistor M11. The gate-source voltage of N-channel MOS transistor M11 becomes equal to those of N-channel MOS transistors M1 and M2.

Temperature compensation voltage generation circuit 51 outputs the voltage at the drain and gate of N-channel MOS transistor M11 as temperature compensation voltage VT. N-channel MOS transistor M11 is diode-connected, and therefore temperature compensation voltage VT is a gate voltage of N-channel MOS transistor M11 at the stable operation point.

The size, that is, L/W of N-channel MOS transistors M1 and M2 differs from the size of N-channel MOS transistor M11. L represents the channel length and W represents the channel width. Therefore, temperature compensation voltage VT varies in accordance with temperature. By changing the magnitude correlation between the size of N-channel MOS transistors M1 and M2 and the size of N-channel MOS transistor M11, it is possible to adjust the temperature characteristic, that is, the degree at which temperature compensation voltage VT varies as temperature varies.

N-channel MOS transistors M11 and M2 have approximately the same size. Accordingly, by changing the number of transistors included in input transistor unit 31, the voltage offset value of temperature compensation voltage VT can be decreased by a factor of the number of transistors included in input transistor unit 31.

FIG. 7 is a graph showing one example of the temperature characteristic of temperature compensation voltage VT.

With reference to FIG. 7, in temperature compensation voltage generation circuit 71 shown in FIG. 3, for example, if the size, that is, L/W of N-channel MOS transistor M1 is larger than that of N-channel MOS transistor M11, temperature compensation voltage VT has a positive temperature characteristic as indicated by G2A of the graph.

In this case, temperature compensation voltage VT is considerably larger than reference input voltage VREFIN. For this reason, for example, a circuit for stepping down reference input voltage VREFIN needs to be prepared separately in addition to temperature compensation voltage generation circuit 71 to generate temperature compensation voltage VT as indicated by G2B of the graph. This causes the circuit scale to become large.

Referring again to FIG. 6, in temperature compensation voltage generation circuit 53 according to the third embodiment of the present invention, input transistor unit 31 further includes N-channel MOS transistor M2 as compared with temperature compensation voltage generation circuit 71. N-channel MOS transistor M2 is diode-connected and connected in series with N-channel MOS transistor M1, and outputs a current in the same direction as that of the output current of N-channel MOS transistor M1. With such a configuration, the voltage at the drain and gate of N-channel MOS transistor M1 of temperature compensation voltage generation circuit 53 is larger than that in temperature compensation voltage generation circuit 71 by the voltage between the gate and source of N-channel MOS transistor M2. That is, temperature compensation voltage VT is one-half the gate-source voltage of N-channel MOS transistor M1. Therefore, in temperature compensation voltage generation circuit 53 according to the third embodiment of the present invention, temperature compensation voltage VT can be prevented from largely deviating from reference input voltage VREFIN without separate provision of a circuit for stepping down reference input voltage VREFIN.

Other configurations and operations are the same as those in the temperature compensation voltage generation circuit according to the first embodiment, and therefore detailed description is not repeated here.

In conventional temperature compensation voltage generation circuits, a circuit of stepping up or stepping down the reference input voltage needs to be provided additionally so as to prevent the output voltage value from largely deviating from the input voltage value. This causes the circuit scale to become large. With the configurations of Patent Documents 1 to 4, it is not possible to step up or step down the input voltage as well as to cause the input voltage to have a temperature characteristic.

However, in temperature compensation voltage generation circuit 53 according to the third embodiment of the present invention, the size of N-channel MOS transistors M1 and M2 included in input transistor unit 31 differs from that of N-channel MOS transistor M11 included in output transistor unit 32. With such a configuration, a voltage which is generated by causing reference input voltage VREFIN to have a temperature characteristic can be obtained. Also, in temperature compensation voltage generation circuit 53 according to the third embodiment of the present invention, the number of transistors included in output transistor unit 32 is smaller than that of transistors included in input transistor unit 31. With such a configuration, a voltage can be generated by stepping down reference input voltage VREFIN. Temperature compensation voltage generation circuit 53 according to the third embodiment of the present invention has a configuration obtained only by adding N-channel MOS transistor M2 to temperature compensation voltage generation circuit 71. A circuit for stepping down reference input voltage VREFIN needs not to be provided additionally, enabling the simplification of the circuit configuration. The current flowing through input transistor unit 31 is the same as that of temperature compensation voltage generation circuit 71, and therefore an increase in power consumption can be prevented.

Thus, in temperature compensation voltage generation circuit 53 according to the third embodiment of the present invention, it is possible to cause the input voltage to have a temperature characteristic as well as to step down the input voltage, and the circuit configuration can be simplified.

Next, another embodiment of the present invention will be described with reference to the drawings. It is to be noted that parts identical or equivalent in the drawings are indicated by the same reference numerals, and description thereof is not repeated.

### Fourth Embodiment

The present embodiment relates to a temperature compensation voltage generation circuit configured to have two stages of subsidiary temperature compensation voltage generation circuits as compared with the temperature compensation voltage generation circuit according to the first embodiment. Content other than that described below is the same as the temperature compensation voltage generation circuit according to the first embodiment.

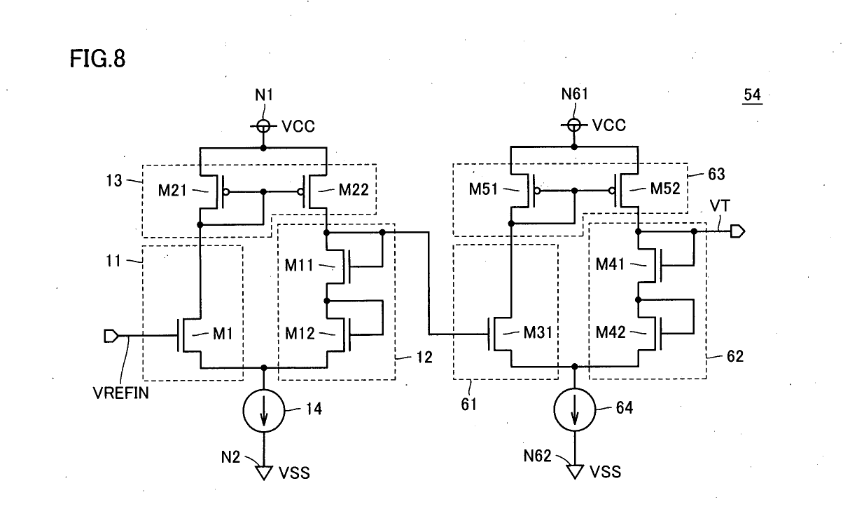

FIG. 8 is a circuit diagram showing the configuration of a temperature compensation voltage generation circuit 54 according to a fourth embodiment of the present invention.

With reference to FIG. 8, temperature compensation voltage generation circuit 54 further includes an input transistor unit 61, a current mirror circuit (output current control circuit) 63 and a constant current source 64 as compared with the temperature compensation voltage generation circuit of the first embodiment of the present invention. Input transistor unit 61 includes N-channel MOS transistor M31. Output transistor unit 62 includes N-channel MOS transistors M41 and M42. Current mirror circuit 63 includes P-channel MOS transistors M51 and M52.

N-channel MOS transistor M31 has its gate to which reference input voltage VREFIN is supplied, its source connected to a first terminal of constant current source 64, and its drain connected to the drain of P-channel MOS transistor M51. A second terminal of constant current source 64 is connected to a ground potential node N62 to which ground voltage VSS is supplied.

N-channel MOS transistors M41 and M42 are each diode-connected. N-channel MOS transistor M42 outputs a current in the same direction as that of the output current of N-channel MOS transistor M41. More specifically, N-channel MOS transistor M41 has its gate and drain connected with each other and its source connected to the gate and the drain of N-channel MOS transistor M42. N-channel MOS transistor M42 has its gate and drain connected with each other and its source connected to the first terminal of constant current source 64.

P-channel MOS transistor M51 has its gate and drain connected with each other and its source connected to a ground potential node N61 to which supply voltage VCC is supplied.

P-channel MOS transistor M52 has its gate connected to the gate and the drain of P-channel MOS transistor M51, its drain connected to the gate and the drain of N-channel MOS transistor M41, and its source connected to ground potential node N61.

P-channel MOS transistors M51 and M52 in current mirror circuit 63 have approximately the same characteristics. With such a configuration, the output current, that is, the current from the drain to the source of N-channel MOS transistor M31 can be approximately equal to the output current, that is, the current from the drain to the source through P-channel MOS transistor M52 and N-channel MOS transistors M41 and M42. The gate-source voltage of each of N-channel MOS transistors M41 and M42 becomes equal to that of N-channel MOS transistor M31. Note that the mirror ratio of current mirror circuit 63 may be other than 1 to 1.

Temperature compensation voltage generation circuit 54 outputs the voltage at the drain and gate of N-channel MOS transistor M41 as temperature compensation voltage VT. N-channel MOS transistor M41 is diode-connected, and therefore temperature compensation voltage VT is a gate voltage of N-channel MOS transistor M41 at the stable operation point.

The size, that is, L/W of N-channel MOS transistor M31 differs from the size of N-channel MOS transistors M41 and M42. L represents the channel length and W represents the channel width. Therefore, temperature compensation voltage VT varies in accordance with temperature. By changing the magnitude correlation between the size of N-channel MOS transistor M31 and the size of N-channel MOS transistors M41 and M42, it is possible to adjust the temperature characteristic, that is, the degree at which temperature compensation voltage VT varies as temperature varies.

N-channel MOS transistors M41 and M42 have approximately the same size. Accordingly, by changing the number of transistors included in output transistor unit 62, the voltage offset value of temperature compensation voltage VT can be increased by a factor of the number of transistors included in output transistor unit 62, that is, by a factor of an integer.

When the size of N-channel MOS transistor M1 is smaller than the size of N-channel MOS transistors M11 and M12 in temperature compensation voltage generation circuit 54, the size of N-channel MOS transistor M31 is made smaller than the size of N-channel MOS transistors M41 and M42. With such a configuration, the negative temperature characteristic that temperature compensation voltage VT has can be further enhanced as compared with temperature compensation voltage generation circuit 51 according to the first embodiment of the present invention.

In temperature compensation voltage generation circuit 54, input transistor unit 11 includes one N-channel MOS transistor and output transistor unit 12 includes two N-channel MOS transistors. An input transistor unit 61 includes one N-channel MOS transistor and output transistor unit 62 includes two N-channel MOS transistors. With such a configuration, temperature compensation voltage VT becomes four times the gate-source voltage of N-channel MOS transistor M1. That is, the step-up rate can be further increased as compared with temperature compensation voltage generation circuit 51 according to the first embodiment of the present invention.

Other configurations and operations are the same as those in the temperature compensation voltage generation circuit according to the first embodiment, and therefore detailed description is not repeated here.

Thus, in temperature compensation voltage generation circuit 54 according to the fourth embodiment of the present invention, as in the temperature compensation voltage generation circuit according to the first embodiment of the present invention, it is possible to cause the input voltage to have a temperature characteristic as well as to step up the input voltage, and the circuit configuration can be simplified.

Note that the magnitude correlation between the size of transistors included in input transistor unit 61 and the size of transistors included in output transistor unit 62 is not limited to the above relationship. If the magnitude correlation between the size of transistors included in input transistor unit 61 and the size of transistors included in output transistor unit 62 is the same as that between the magnitude correlation between the size of transistors included in input transistor unit 11 and the size of transistors included in output transistor unit 12, the temperature characteristic that temperature compensation voltage VT has can be further enhanced as compared with temperature compensation voltage generation circuit 51 according to the first embodiment of the present invention.

The magnitude correlation between the number of transistors included in input transistor unit 61 and the number of transistors included in output transistor unit 62 is not limited to the above relationship. If the magnitude correlation between the number of transistors included in input transistor unit 61 and the number of transistors included in output transistor unit 62 is the same as that between the magnitude correlation between the number of transistors included in input transistor unit 11 and the number of transistors included in output transistor unit 12, the step-up rate or step-down rate can be further enhanced as compared with temperature compensation voltage generation circuit 51 according to the first embodiment of the present invention.

Next, another embodiment of the present invention will be described with reference to the drawings.

### Fifth Embodiment

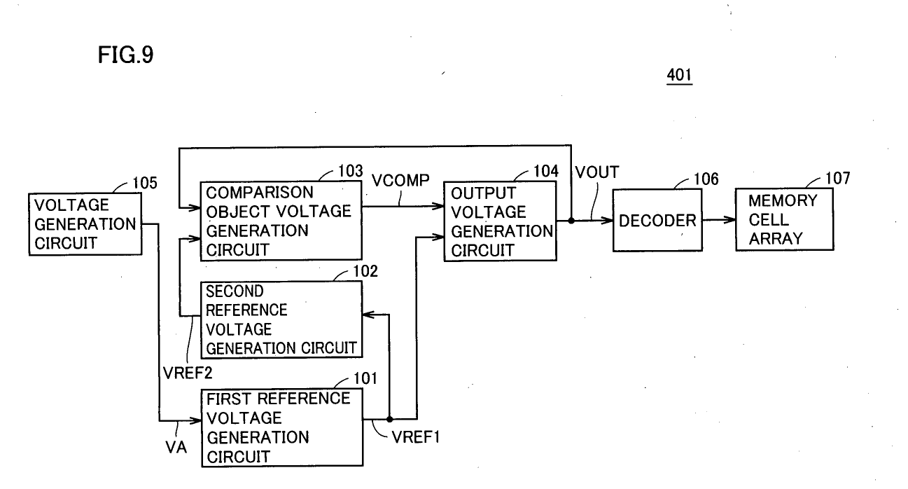

FIG. 9 is a functional block diagram showing the configuration of a semiconductor device 401 according to a fifth embodiment of the present invention.

With reference to FIG. 9, semiconductor device 401 includes a first reference voltage generation circuit 101, a second reference voltage generation circuit 102, a comparison object voltage generation circuit 103, an output voltage generation circuit 104, a voltage generation circuit 105, a decoder 106 and a memory cell array 107.

Based on a voltage VA received from voltage generation circuit 105, first reference voltage generation circuit 101 generates a reference voltage VREF1 whose value varies in accordance with the external factor. Examples of the external factor as used herein include ambient temperature of first reference voltage generation circuit 101, a value of a supply voltage supplied to first reference voltage generation circuit 101, and a frequency of a signal first reference voltage generation circuit 101 receives.

Output voltage generation circuit 104 compares reference voltage VREF1 received from first reference voltage generation circuit 101 with comparison object voltage VCOMP received from comparison object voltage generation circuit 103, generates output voltage VOUT based on the comparison result, and outputs it to decoder 6 and comparison object voltage generation circuit 103. Note that output voltage generation circuit 104 may be a voltage down converter (VDC), be a regulator, and have the configuration including a charge pump as described later.

Based on reference voltage VREF1 received from first reference voltage generation circuit 101, second reference voltage generation circuit 102 generates a plurality of voltages smaller than reference voltage VREF1, selects one of the plurality of voltages, and outputs it as reference voltage VREF2.

Based on output voltage VOUT received from output voltage generation circuit 104 and reference voltage VREF2 received from second reference voltage generation circuit 102, comparison object voltage generation circuit 103 generates comparison object voltage VCOMP having a voltage value smaller than that of output voltage VOUT. With such a configuration, the withstand voltage of transistors and the like included in output voltage generation circuit 104 can be reduced. For example, the voltage that a comparison circuit 131, which will be described later, in output voltage generation circuit 104 receives can be made smaller than output voltage VOUT, and therefore the transistors included in comparison circuit 131 can be prevented from being broken.

Comparison object voltage generation circuit 103 can change the value of comparison object voltage VCOMP, e.g., by an internal switch. With such a configuration, the value of output voltage VOUT can be changed. Based on output voltage VOUT received from output voltage generation circuit 104, decoder 106 generates write voltage, read voltage, erase voltage and the like, and outputs them to a memory cell array 107. For example, based on output voltage VOUT received from output voltage generation circuit 104, decoder 106 supplies voltage to word lines in memory cell array 107.

For example, memory cell array 107 includes a plurality of memory cells that store data, and stores data, outputs the stored data, and erases the stored data based on write voltage, read voltage, erase voltage and the like received from decoder 106.

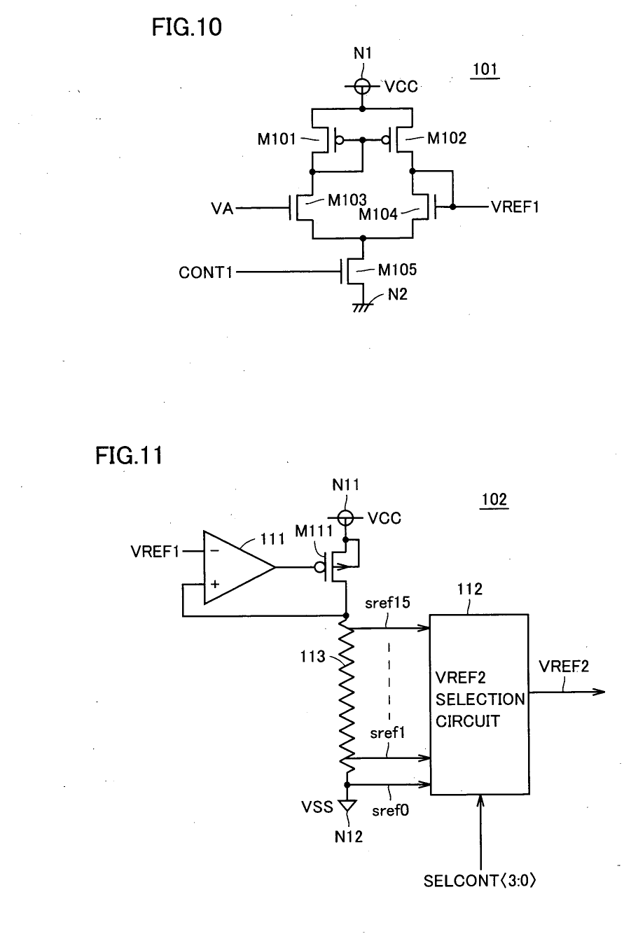

FIG. 10 is a circuit diagram showing the configuration of first reference voltage generation circuit 101 in semiconductor device 401 according to the fifth embodiment of the present invention.

With reference to FIG. 10, first reference voltage generation circuit 101 includes P-channel MOS transistors (insulated-gate field-effect transistors) M101 and M102 and N-channel MOS transistors M103 to M105.

The sources of P-channel MOS transistors M101 and M102 are connected to power source potential node N1 to which supply voltage VCC is supplied. The gate of P-channel MOS transistor M101 is connected to the drain of P-channel MOS transistor M101, the drain of N-channel MOS transistor M103 and the gate of P-channel MOS transistor M102. The source of N-channel MOS transistor M103 is connected to the drain of N-channel MOS transistor M105 and the source of N-channel MOS transistor M104. The drain of P-channel MOS transistor M102 is connected to the drain and the gate of N-channel MOS transistor M104. The source of N-channel MOS transistor M105 is connected to a ground potential node N2 to which the ground voltage is supplied. Voltage VA from voltage generation circuit 105 is supplied to the gate of N-channel MOS transistor M103. A control voltage CONT1 from a controller (not shown) included in semiconductor device 401 is supplied to the gate of N-channel MOS transistor M105.

First reference voltage generation circuit 101 outputs the voltage at the drain and gate of N-channel MOS transistor M104 as reference voltage VREF1. That is, since N-channel MOS transistor M104 is diode-connected, reference voltage VREF1 is a gate voltage of N-channel MOS transistor M104 at the stable operation point. First reference voltage generation circuit 101 outputs reference voltage VREF1 if N-channel MOS transistor M105 is turned on by control voltage CONT1.

The sizes, that is, LUV of N-channel MOS transistors M103 and M104 differ from each other. L represents the channel length and W represents the channel width. Therefore, reference voltage VREF1 varies in accordance with temperature. By changing the magnitude correlation of N-channel MOS transistors M103 and M104, it is possible to adjust the temperature characteristic, that is, the degree at which temperature compensation voltage VT varies as temperature varies.

FIG. 11 is a circuit diagram showing the configuration of second reference voltage generation circuit 102 in semiconductor device 401 according to the fifth embodiment of the present invention.

With reference to FIG. 11, second reference voltage generation circuit 102 includes a comparison circuit 111, a VREF2 selection circuit 112, a resistor 113 and a P-channel MOS transistor M111.

Reference voltage VREF1 from first reference voltage generation circuit 101 is supplied to an inverted input terminal of comparison circuit 111. A non-inverted input terminal is connected to the drain of P-channel MOS transistor M111 and a first end of resistor 113. The source of P-channel MOS transistor M111 is connected to a power source potential node N11 of supply voltage VCC. A second end of resistor 113 is connected to a power source potential node N12 to which ground voltage VSS is supplied.

Comparison circuit 111 compares reference voltage VREF1 with the drain voltage of P-channel MOS transistor M111, and supplies a voltage to the gate of P-channel MOS transistor M111 based on the comparison result. That is, the voltage at the first end of resistor 113 becomes very close to reference voltage VREF1.

Resistor 113 generates voltages sref0 to sref15 by dividing the voltage at the first end, that is, reference voltage VREF1, and outputs the generated voltages to VREF2 selection circuit 112. For example, voltage sref0 becomes ground voltage VSS, voltage sref1 becomes a voltage of 1/16 of reference voltage VREF1, voltage sref2 becomes a voltage of 2/16 of reference voltage VREF1, and voltage sref15 becomes a voltage of 15/16 of reference voltage VREF1.

VREF2 selection circuit 112 selects one of voltages sref0 to sref15 based on a 4-bit selection control signal SELCONT received, e.g., from a controller (not shown) included in semiconductor device 401, and outputs the selected voltage to comparison object voltage generation circuit 103 as reference voltage VREF2.

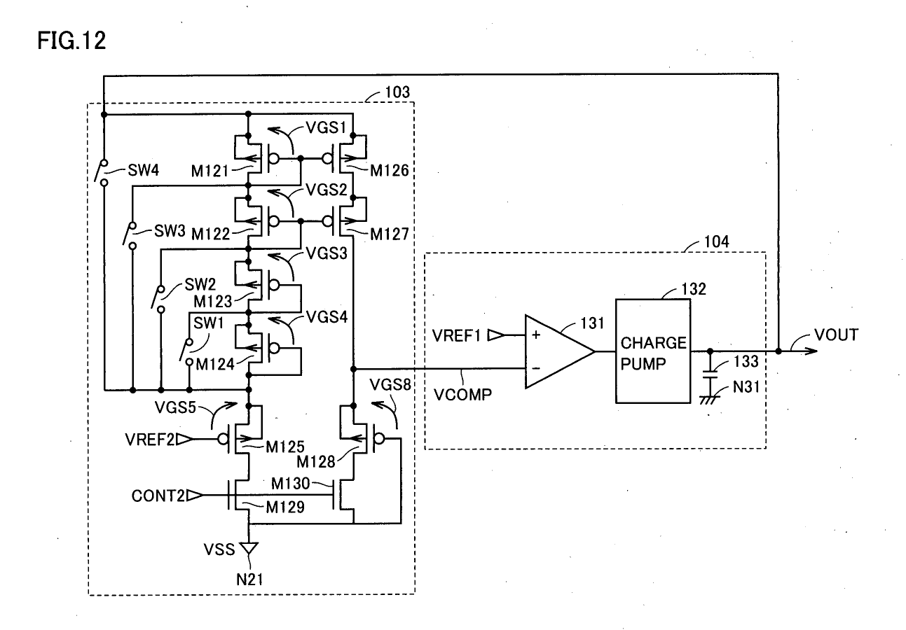

FIG. 12 is a circuit diagram showing the configuration of comparison object voltage generation circuit 103 and output voltage generation circuit 104 in semiconductor device 401 according to the fifth embodiment of the present invention.

With reference to FIG. 12, comparison object voltage generation circuit 103 includes P-channel MOS transistors M121 to M127, N-channel MOS transistors M128 to M130 and switches SW1 to SW4.

The gate of P-channel MOS transistor M121 is connected to the drain of P-channel MOS transistor M121, the gate of P-channel MOS transistor M126, and the source of P-channel MOS transistor M122. The gate of P-channel MOS transistor M122 is connected to the drain of P-channel MOS transistor M122, the gate of P-channel MOS transistor M127, and the source of P-channel MOS transistor M123. The gate and the drain of P-channel MOS transistor M123 are connected to the source of P-channel MOS transistor M124. The gate and the drain of P-channel MOS transistor M124 are connected to the source of P-channel MOS transistor M125. The drain of P-channel MOS transistor M125 is connected to the drain of N-channel MOS transistor M129. The drain of P-channel MOS transistor M126 is connected to the source of P-channel MOS transistor M129. The drain of P-channel MOS transistor M127 is connected with the source of P-channel MOS transistor M128. The drain of P-channel MOS transistor M128 is connected with the drain of N-channel MOS transistor M130. The gate of P-channel MOS transistor M128, the source of N-channel MOS transistor M129 and the source of N-channel MOS transistor M130 are connected to a power source potential node N21 to which ground voltage VSS is supplied.

Switch SW1 has a first end connected to the source of P-channel MOS transistor M125, and a second end connected to the source of P-channel MOS transistor M124. Switch SW2 has a first end connected to the source of P-channel MOS transistor M125, and a second end connected to the source of P-channel MOS transistor M123. Switch SW3 has a first end connected to the source of P-channel MOS transistor M125, and a second end connected to the source of P-channel MOS transistor M122. Switch SW4 has a first end connected to the source of P-channel MOS transistor M125, and a second end connected to the source of P-channel MOS transistor M121.

Output voltage VOUT from output voltage generation circuit 104 is supplied to the source of P-channel MOS transistor M121 and the source of P-channel MOS transistor M126. Reference voltage VREF2 from second reference voltage generation circuit 102 is supplied to the gate of P-channel MOS transistor M125. A control voltage CONT2 from a controller (not shown) included in semiconductor device 401 is supplied to the gates of N-channel MOS transistors M129 and M130.

Comparison object voltage generation circuit 103 outputs a voltage at the source of P-channel MOS transistor M128 to output voltage generation circuit 104 as comparison object voltage VCOMP. Comparison object voltage generation circuit 103 outputs comparison object voltage VCOMP if N-channel MOS transistors M129 and M130 are turned on by control voltage CONT2.

Switches SW1 to SW4 switch the value of comparison object voltage VCOMP. Switches SW1 to SW4 are controlled such that one of the switches is in ON state and other switches are in OFF states, or all the switches are in OFF states.

For example, if all switches SW1 to SW4 are in OFF states, P-channel MOS transistors M121 to M125 become active. That is, the number of rows of P-channel MOS transistors of input rows in comparison object voltage generation circuit 103 is five.

If switch SW1 is in ON state and switches SW2 to SW4 are in OFF states, P-channel MOS transistors M121 to M123 and M125 become active. That is, the number of rows of P-channel MOS transistors of input rows in comparison object voltage generation circuit 103 is four.

If switch SW2 is in ON state and switches SW1, SW3 and SW4 are in OFF states, P-channel MOS transistors M121, M122 and M125 become active. That is, the number of rows of P-channel-MOS transistors of input rows in comparison object voltage generation circuit 103 is three.

If switch SW3 is in ON state and switches SW1, SW2 and SW4 are in OFF states, P-channel MOS transistors M121 and M125 become active. That is, the number of rows of P-channel MOS transistors of input rows in comparison object voltage generation circuit 103 is two.

If switch SW4 is in ON state and switches SW1 to SW3 are in OFF states, P-channel MOS transistor M125 becomes active. That is, the number of rows of P-channel MOS transistors of input rows in comparison object voltage generation circuit 103 is one.

Note that the configuration of comparison object voltage generation circuit 103 is not limited to one including a plurality of MOS transistors, but may be the configuration including resistances instead of MOS transistors. However, in order to increase the efficiency of charge pump 132, the output current of charge pump 132 needs to be reduced. For this reason, if comparison object voltage generation circuit 103 is composed of resistances, the value of resistance needs to be increased. In this case, the area of resistances becomes large, making it difficult to reduce the size of the circuit. Therefore, it is preferable that comparison object voltage generation circuit 103 be composed of MOS transistors.

Output voltage generation circuit 104 includes comparison circuit 131, charge pump 132 and a capacitor 133. Capacitor 133 has a first electrode connected to the output of charge pump 132, and a second electrode connected to a ground potential node N31 to which the ground voltage is supplied.

Comparison circuit 131 compares reference voltage VREF1 received at non-inverted input terminal from first reference voltage generation circuit 101 with comparison object voltage VCOMP received at the inverted input terminal from comparison object voltage generation circuit 103, and outputs a voltage of logic high level or logic low level to charge pump 132 based on the result of the comparison. More specifically, comparison circuit 131 outputs a voltage of logic high level to charge pump 132 if comparison object voltage VCOMP is smaller than reference voltage VREF1. On the other hand, comparison circuit 131 outputs a voltage of logic low level to charge pump 132 if comparison object voltage VCOMP is larger than reference voltage VREF1.

When receiving a voltage of logic high level from comparison circuit 131, charge pump 132 stores charge on capacitor 133. When receiving a voltage of logic low level from comparison circuit 131, charge pump 132 stops the operations. That is, the charge storage on capacitor 133 is stopped.

Output voltage generation circuit 104 outputs a voltage at a first electrode of capacitor 133 as output voltage VOUT.

Output voltage VOUT is represented in the following equation:

VOUT=VREF1×N+VREF2

where the value of reference voltage VREF1 is VREF1; the value of reference voltage VREF2 is VREF2; and the number of rows of P-channel MOS transistors of input rows in comparison object voltage generation circuit 103 is N.

Next, operations of semiconductor device 401 will be described with specific numeric values. For simplified description, it is assumed that reference voltage VREF2 is set to 0 V. It is also assumed that the number of rows of P-channel MOS transistors of input rows in comparison object voltage generation circuit 103 is set to 5.

In a case where output voltage VOUT needs to be 8 V, reference voltage VREF1 is set to 1.6 V. In this case, second reference voltage generation circuit 102 is allowed to select one of voltages from 0 V to 1.5 V in 100 mV steps and outputs the selected one as reference voltage VREF2.

Under a condition of output voltage VOUT e.g., of 5 V, each of gate-source voltages VGS1 to VGS5 of P-channel MOS transistors M121 to M125 is 1 V. As a result, gate-source voltage V6S8 of P-channel MOS transistor M128, that is, comparison object voltage VCOMP becomes 1 V.

At this point, comparison circuit 131 outputs a voltage of logic high level to charge pump 132 because comparison object voltage VCOMP is smaller than reference voltage VREF1.

Charge pump 132 receives a voltage of logic high level from comparison circuit 131 and stores charge on capacitor 133 to increase output voltage VOUT.

On the other hand, under a condition of output voltage VOUT, e.g., of 9 V, each of gate-source voltages VGS1 to VGS5 of P-channel MOS transistors M121 to M125 is 1.8 V. As a result, gate-source voltage VGS8 of P-channel MOS transistor M128, that is, comparison object voltage VCOMP becomes 1.8 V.

At this point, comparison circuit 131 outputs a voltage of logic low level to charge pump 132 because comparison object voltage VCOMP is larger than reference voltage VREF1.

Charge pump 132 receives a voltage of logic low level from comparison circuit 131 and stops storing charge on capacitor 133. This causes output voltage VOUT to become small.

Feedback operations as described above in semiconductor device 401 according to the fifth embodiment of the present invention enable output voltage VOUT to become very close to a desired voltage, 8 V in this case.

In semiconductor device 401 according to the fifth embodiment of the present invention, first reference voltage generation circuit 101 generates reference voltage VREF1 whose voltage value varies in accordance with external factors based on voltage VA received from voltage generation circuit 105. Then, output voltage generation circuit 104 compares reference voltage VREF1 received from first reference voltage generation circuit 101 with comparison object voltage VCOMP received from comparison object voltage generation circuit 103, and generates output voltage VOUT based on the result of the comparison. With such a configuration, it is possible to appropriately cope with characteristics derived from external factors of an element to which the output voltage is supplied.

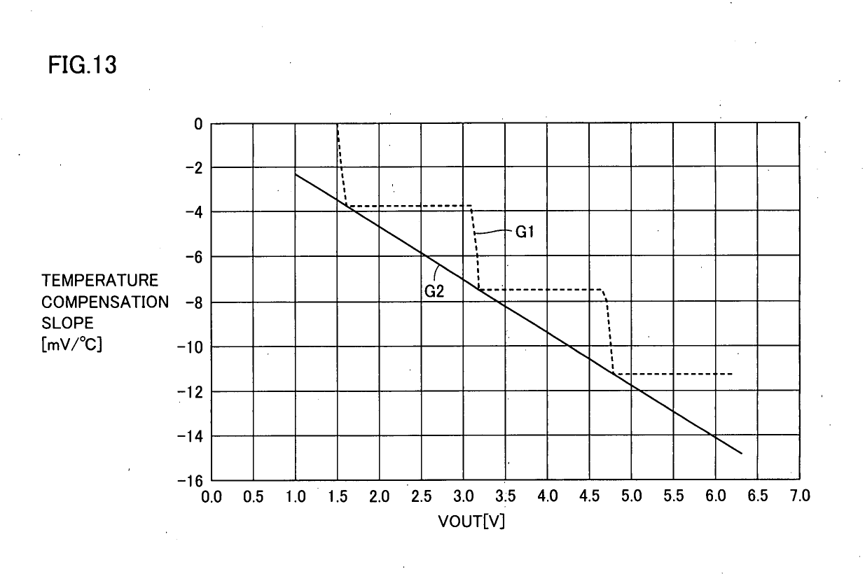

FIG. 13 is a graph showing a relationship between the voltage value and the temperature characteristic of output voltage VOUT of semiconductor device 401 according to the fifth embodiment of the present invention.

As described above, by changing settings in ON state and in OFF state of switches SW1 to SW4 in comparison object voltage generation circuit 103, the number of rows of P-channel MOS transistors of input rows in comparison object voltage generation circuit 103 are increased and decreased. This increase and decrease of the number of rows causes the increase and decrease of the value of comparison object voltage VCOMP. With such a configuration, the value of output voltage VOUT can be changed.

G1 of the graph indicates a case where it is assumed that semiconductor device 401 does not generate reference voltage VREF2 and accordingly comparison object voltage VCOMP is generated based on only output voltage VOUT and the number of rows of P-channel MOS transistors of input rows in comparison object voltage generation circuit 103. G2 of the graph indicates a case where comparison object voltage VCOMP is generated based on output voltage VOUT, the number of rows of P-channel MOS transistors of input rows in comparison object voltage generation circuit 103, and reference voltage VREF2 having the same temperature characteristic as that of reference voltage VREF1, as in semiconductor device 401 according to the fifth embodiment of the present invention.

G1 of the graph indicates that the temperature characteristic of output voltage VOUT varies in a stepped pattern in accordance with the set value of output voltage VOUT, that is, the number of rows of P-channel MOS transistors of input rows in comparison object voltage generation circuit 103. For example, in a case where output voltage VOUT is set from 1.6 V to 3.1 V by setting the number of rows of P-channel MOS transistors of input rows in comparison object voltage generation circuit 103 to one, the temperature characteristic of output voltage VOUT becomes −3.8 mV/° C. In another case where output voltage VOUT is set from 3.2 V to 4.7 V by setting the number of rows of P-channel MOS transistors of input rows in comparison object voltage generation circuit 103 to two, the temperature characteristic of output voltage VOUT becomes −7.6 mV/° C.

A case is discussed where output voltage VOUT of one of two semiconductor devices 401 is within the required voltage range whereas output voltage VOUT of the other of two semiconductor devices 401 is out of the required voltage range, which is caused by non-uniformity of internal components. If it is assumed that the number of rows of P-channel MOS transistors in input rows in comparison object voltage generation circuit 103 of semiconductor device 401 in which output voltage VOUT is within the required voltage range is one, the number of rows of P-channel MOS transistors of input rows in comparison object voltage generation circuit 103 of semiconductor device 401 in which output voltage VOUT is not within the required voltage range needs to be, e.g., two. In this case, temperature characteristic of output voltage VOUT largely differs between two semiconductor devices 401.

However, in semiconductor device 401 according to the fifth embodiment of the present invention, second reference voltage generation circuit 102 generates a plurality of voltages smaller than reference voltage VREF1 based on reference voltage VREF1, and selects one of the plurality of voltages and outputs the selected one as reference voltage VREF2. Comparison object voltage generation circuit 103 generates comparison object voltage VCOMP based on output voltage VOUT received from output voltage generation circuit 104 and reference voltage VREF2 received from second reference voltage generation circuit 102. Such a configuration as described where reference voltage VREF2 can be selected from a plurality of voltages smaller than reference voltage VREF1 enables fine adjustment of output voltage VOUT in accordance with non-uniformity of internal components as compared with a case where it is assumed that comparison object voltage VCOMP is generated based on only output voltage VOUT and the number of rows of P-channel MOS transistors of input rows in comparison object voltage generation circuit 103 as indicated by G1 of the graph.

Reference voltage VREF2 is a voltage generated based on reference voltage VREF1, that is, a voltage generated by dividing reference voltage VREF1, and therefore has the same temperature characteristic as that of reference voltage VREF1. Therefore, as indicated by G2 of the graph, the temperature characteristic of output voltage VOUT can be adjusted accurately in accordance with the value of output voltage VOUT. As compared with a case where it is assumed that comparison object voltage VCOMP is generated based on only output voltage VOUT and the number of rows of P-channel MOS transistors of input rows in comparison object voltage generation circuit 103 as indicated by G1 of the graph, the temperature characteristic of output voltage VOUT can be adjusted finely in accordance with the value of output voltage VOUT as indicated by G2 of the graph.

As described above, in semiconductor device 401 according to the fifth embodiment of the present invention, it is possible to appropriately cope with characteristics derived from external factors of an element to which the output voltage is supplied and to prevent non-uniformity among output voltage values and characteristics of the output voltages.

Next, another embodiment of the present invention will be described with reference to the drawings. It is to be noted that parts identical or equivalent in the drawings are indicated by the same reference numerals, and description thereof is not repeated.

### Sixth Embodiment

The present embodiment relates to a semiconductor device configured to generate a plurality of kinds of output voltages as compared to a semiconductor device according to the fifth embodiment. Content other than that described below is the same as the temperature compensation voltage generation circuit according to the first embodiment.

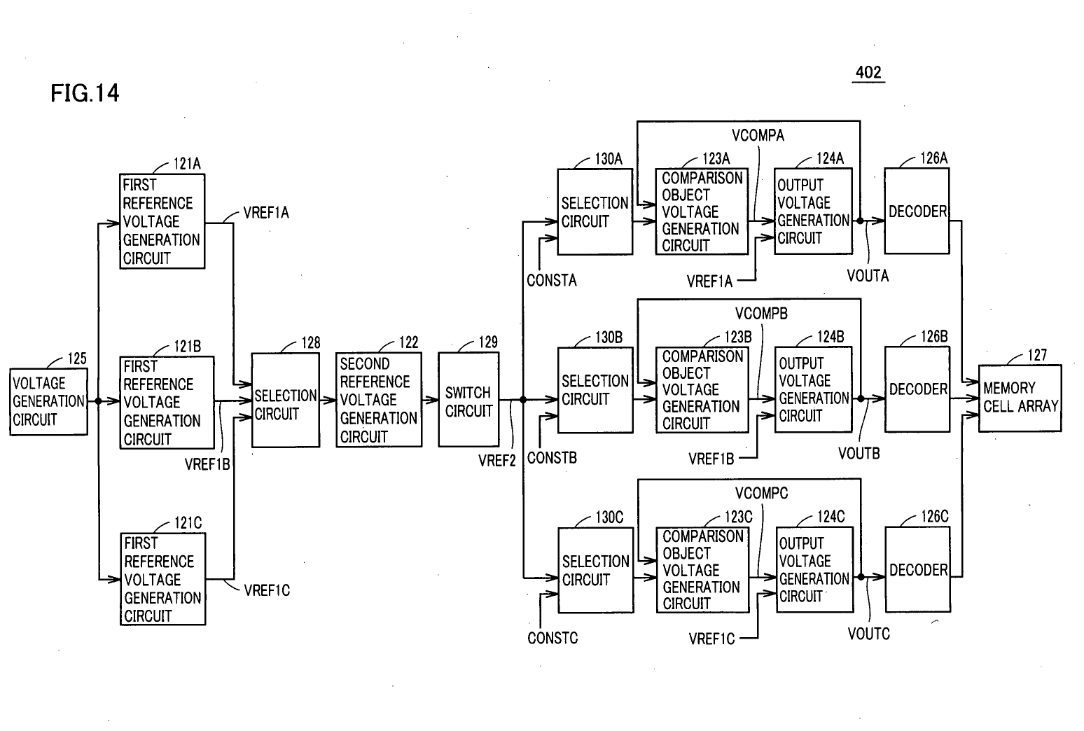

FIG. 14 is a functional block diagram showing the configuration of semiconductor device 402 according to a sixth embodiment of the present invention.

With reference to FIG. 14, semiconductor device 402 includes first reference voltage generation circuits 121A to 121C, a second reference voltage generation circuit 122, comparison object voltage generation circuits 123A to 123C, output voltage generation circuits 124A to 124C, a voltage generation circuit 125, decoders 126A to 126C, a memory cell array 127, a selection circuit 128, a switch circuit 129 and selection circuits 130A to 130C.

Based on voltage VA received from voltage generation circuit 105, first reference voltage generation circuits 121A to 121C generate reference voltages VREF1A, VREF1B and VREF1C whose voltage values vary in accordance with external factors, respectively. Examples of external factors as used herein include ambient temperature of first reference voltage generation circuits 121A to 121C, values of supply voltages supplied to first reference voltage generation circuits 121A to 121C, and frequencies of signals first reference voltage generation circuits 121A to 121C receive.

Output voltage generation circuits 124A to 124C compare reference voltages VREF1A, VREF1B and VREF1C received from first reference voltage generation circuits 121A to 121C, respectively, with comparison object voltages VCOMPA, VCOMPB and VCOMPC received from comparison object voltage generation circuits 123A to 123C, respectively. Based on the result of the comparison, output voltage generation circuits 124A to 124C generate output voltages VOUTA, VOUTB and VOUTC and outputs them to decoders 126A to 126C and comparison object voltage generation circuits 123A to 123C, respectively. Note that output voltage generation circuits 124A to 124C may be voltage down converters (VDCs), be regulators, and have the configuration including a charge pump just as in semiconductor device 401 according to the fifth embodiment of the present invention.

Selection circuit 128 selects one of reference voltages VREF1A, VREF1B and VREF1C received from first reference voltage generation circuits 121A to 121C, respectively, and outputs the selected one to second reference voltage generation circuit 122 as reference voltage VREF1.

Second reference voltage generation circuit 122 generates a plurality of voltages smaller than reference voltage VREF1 received from selection circuit 128 based on reference voltage received from selection circuit 128, and selects one of the plurality of voltages and outputs the selected one as reference voltage VREF2.

Switch circuit 129 outputs reference voltage VREF2 received from second reference voltage generation circuit 122 to a selection circuit corresponding to a first reference voltage generation circuit that has generated selected reference voltage VREF1, among selection circuits 130A to 130C.

Selection circuits 130A to 130C output either one of reference voltage VREF2 received from switch circuit 129 and reference voltages CONSTA, CONSTB and CONSTC without temperature characteristics each received from a voltage generation circuit (not shown), as reference voltage VREF2, to comparison object voltage generation circuit 123A to 123C.

Comparison object voltage generation circuits 123A to 123C generate comparison object voltages VCOMPA, VCOMPB and VCOMPC having voltage values smaller than output voltages VOUTA, VOUTB and VOUTC, respectively, based on output voltages VOUTA, VOUTB and VOUTC received from output voltage generation circuits 124A to 124C, respectively, and reference voltage VREF2 received from second reference voltage generation circuit 122. With such a configuration, the withstand voltage of transistors and the like included in output voltage generation circuits 124A to 124C can be reduced. For example, voltages that comparison circuits 131 in output voltage generation circuits 124A to 124C receive can be made smaller than output voltages VOUTA, VOUTB and VOUTC, and therefore the transistors included in comparison circuits 131 can be prevented from being broken.

Regarding comparison object voltage generation circuits 123A to 123C, the voltage values of comparison object voltages VCOMPA, VCOMPB and VCOMPC can be changed, e.g., by internal switches. With such a configuration, the voltage values of output voltages VOUTA, VOUTB and VOUTC can each be changed.

Decoders 126A to 126C generate, based on output voltages VOUTA, VOUTB and VOUTC received from output voltage generation circuits 124A to 124C, respectively, write voltage, read voltage, erase voltage and the like, and outputs them to a memory cell array 127. For example, decoders 126A to 126C supply, based on output voltages VOUTA, VOUTB and VOUTC received from output voltage generation circuits 124A to 124C, respectively, voltage to word lines, source lines and bit lines in memory cell array 127, respectively.

For example, memory cell array 127 includes a plurality of memory cells that store data, and stores data, outputs the stored data, and erases the stored data based on write voltage, read voltage, erase voltage and the like received from decoders 126A to 126C.

Other configurations and operations are the same as those in the semiconductor device according to the fifth embodiment, and therefore detailed description is not repeated here.

Thus, in the semiconductor device according to the sixth embodiment of the present invention, as in the fifth embodiment of the present invention, it is possible to appropriately cope with characteristics derived from external factors of an element to which the output voltage is supplied and to prevent non-uniformity among output voltage values and characteristics of the output voltages.

If it is sufficient only to make one of voltages supplied to word lines, source lines, bit lines and the like in memory cell array 127 suited for temperature characteristics of memory cells, the chip area of semiconductor device 401 can be reduced by employing a configuration of sharing a second reference voltage generation circuit among output voltages VOUTA to VOUTC as mentioned above.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a first input transistor unit including a first transistor having a control electrode to which a reference voltage is supplied;
a first output transistor unit including a diode-connected second transistor; and
a first output current control circuit causing a current corresponding to a current flowing between conductive electrodes of said first transistor to flow between conductive electrodes of said second transistor, wherein
at least one of said first input transistor unit and said first output transistor unit further includes one or more third transistors being diode-connected and connected in series with corresponding one of said first transistor and said second transistor to output a current in a same direction as a direction of an output current of said corresponding one of said first transistor and said second transistor,
a total number of said first transistors and said third transistors in said first input transistor unit differs from a total number of said second transistors and said third transistors in said first output transistor unit,
a size of said first transistor and a size of said one or more third transistors in said first input transistor unit differ from a size of said second transistor and a size of said one or more third transistors in said first output transistor unit, and
a voltage at a control electrode of said second transistor is an output voltage.

2. The semiconductor device according to claim 1, wherein
the total number of said first transistors and said third transistors in said first input transistor unit is smaller than the total number of said second transistor and said third transistors in said first output transistor unit, and
the size of said first transistor and the size of said one or more third transistors in said first input transistor unit are smaller than the size of said second transistor and the size of said one or more third transistors in said first output transistor unit.

3. The semiconductor device according to claim 1, wherein
the total number of said first transistors and said third transistors in said first input transistor unit is larger than the total number of said second transistors and said third transistors in said first output transistor unit, and
the size of said first transistor and the size of said one or more third transistors in said first input transistor unit are larger than the size of said second transistor and the size of said one or more third transistors in said first output transistor unit.

4. The semiconductor device according to claim 1, wherein said first input transistor unit includes said first transistor and said one or more third transistors having an approximately equal size.

5. The semiconductor device according to claim 1, wherein said first output transistor unit includes said second transistor and said one or more third transistors having an approximately equal size.

6. The semiconductor device according to claim 1, further comprising:
a second input transistor unit including a fourth transistor having a control electrode coupled to the control electrode of said second transistor;
a second output transistor unit including a diode-connected fifth transistor; and
a second output current control circuit causing a current corresponding to a current flowing between conductive electrodes of said fourth transistor to flow between conductive electrodes of said fifth transistor, wherein
at least one of said second input transistor unit and said second output transistor unit further includes one or more sixth transistors being diode-connected and connected in series with corresponding one of said fourth transistor and said fifth transistor to output a current in a same direction as a direction of an output current of said corresponding one of said fourth transistor and said fifth transistor,
a magnitude correlation between a total number of said fourth transistors and said sixth transistors in said second input transistor unit and a total number of said fifth transistors and said sixth transistors in said second output transistor unit is same as a magnitude correlation between the total number of said first transistors and said third transistors in said first input transistor unit and the total number of said second transistor and said third transistors in said first output transistor unit,
a magnitude correlation between a size of said fourth transistor as well as a size of said one or more sixth transistors in said second input transistor unit and a size of said fifth transistor as well as a size of said one or more sixth transistors in said second output transistor unit is same as a magnitude correlation between the size of said first transistor as well as the size of said one or more third transistors in said first input transistor unit and the size of said second transistor as well as the size of said one or more third transistors in said first output transistor unit, and
a voltage at a control electrode of said fifth transistor is an output voltage.

7. A semiconductor device comprising:
a first reference voltage generation circuit generating a first reference voltage having a voltage value varying in accordance with an external factor;
an output voltage generation circuit performing a comparison of said first reference voltage with a comparison object voltage, and generating an output voltage based on a result of said comparison;
a second reference voltage generation circuit generating, based on said first reference voltage, a plurality of voltages smaller than said first reference voltage, and selecting one of said plurality of voltages and outputting the selected voltage as a second reference voltage; and
a comparison object voltage generation circuit generating said comparison object voltage based on said output voltage and said second reference voltage.

8. The semiconductor device according to claim 7, wherein said comparison object voltage generation circuit generates, based on said output voltage and said second reference voltage, said comparison object voltage having a voltage value smaller than said output voltage.

9. The semiconductor device according to claim 7, wherein said comparison object voltage generation circuit includes:
a first transistor having a control electrode, a first conductive electrode to which said output voltage is supplied, and a second conductive electrode coupled with said control electrode;
a second transistor having a control electrode to which said second reference voltage is supplied, a first conductive electrode coupled with the second conductive electrode of said first transistor, and a second conductive electrode coupled to a fixed potential node to which a fixed voltage is supplied;
a third transistor having a control electrode coupled with the control electrode of said first transistor, a first conductive electrode to which said output voltage is supplied, and a second conductive electrode; and
a fourth transistor having a first conductive electrode coupled with the second conductive electrode of said third transistor, and a control electrode and a second conductive electrode coupled to said fixed potential node, and
said comparison object voltage generation circuit outputs a voltage at said first conductive electrode of said fourth transistor as said comparison object voltage.

10. The semiconductor device according to claim 9, wherein said comparison object voltage generation circuit further includes:
a switch having a first end coupled to the first conductive electrode of said first transistor, and a second end coupled to the second conductive electrode of said first transistor.

11. The semiconductor device according to claim 7, wherein said external factor is one of ambient temperature of said first reference voltage generation circuit, a power source voltage value supplied to said first reference voltage generation circuit, and a frequency of a signal received by said first reference voltage generation circuit.

12. The semiconductor device according to claim 7, comprising:
a plurality of said first reference voltage generation circuits;
one said second reference voltage generation circuit;
a plurality of said comparison object voltage generation circuits respectively corresponding to said plurality of said first reference voltage generation circuits;
a plurality of said output voltage generation circuits respectively corresponding to said plurality of said first reference voltage generation circuits, and each performing a comparison of said first reference voltage received from a corresponding one of said first reference voltage generation circuits with said comparison object voltage received from a corresponding one of said comparison object voltage generation circuits to generate said output voltage based on a result of said comparison;
a selection circuit selecting one of said first reference voltages received from said plurality of first reference voltage generation circuits and outputting the selected voltage to said second reference voltage generation circuit; and
a switch circuit outputting said second reference voltage received from said second reference voltage generation circuit to said comparison object voltage generation circuit corresponding to said first reference voltage generation circuit that has generated said selected one of said first reference voltages.
